(19) United States
(12) Patent Application Publication
(10) Pub. No.: US 2002/0068376 A1
(43) Pub. Date: Jun. 6, 2002

(54) METHOD FOR FABRICATING CONTACT HOLE

(76) Inventor: CHI-KUO HSIEH, HSINCHU (TW)

Correspondence Address: J.C. PATENTS INC., 4 VENTURE, SUITE 250, IRVINE, CA, 92618, US

(21) Appl. No.: 09/241,527

(22) Filed: Feb. 1, 1999

(30) Foreign Application Priority Data
Jan. 4, 1999 (TW) 88100006

(51) Int. Cl. H01L 21/00; H01L 21/8238; H01L 21/265; H01L 21/425; H01L 21/4763

(52) U.S. Cl. 438/98; 438/233; 438/523; 438/533

(57) ABSTRACT

An improved method of fabricating a contact hole is provided. A semiconductor substrate is provided wherein a transistor is formed on the substrate. A dielectric layer is formed over the substrate. A patterned mask layer with an opening is formed on the dielectric layer. An UV curing treatment is performed on the mask layer. The dielectric layer is anisotropically etched using the mask layer as a mask to form a contact hole in the dielectric layer.

### CROSS-REFERENCE TO RELATED APPLICATION

This application claims the priority benefit of Taiwan application serial no. 88100006, filed Jan. 4, 1999, the full disclosure of which is incorporated herein by reference.

### BACKGROUND OF THE INVENTION

1. Field of Invention

The present invention relates to a semiconductor process. More particularly, the present invention relates to a method for fabricating a contact hole.

2. Description of Related Art

In semiconductor processes, a conductive line is formed between the two conductive layers as an electrical connection. The conductive line is called a via plug. If the conductive line is formed between a metal layer and a metal oxide semiconductor (MOS) as an electrical connection, the conductive line is called a contact plug. With the increasing integration in integrated circuits, the aspect ratio of the via hole or the contact hole becomes larger and larger so that a step coverage ability and a gap filling ability become worse. Therefore, voids easily occur in plugs or an overhang is easily generated so as to decrease device quality.

One of the conventional resolution to this problem is to change a profile of the via hole or the contact hole. Tops of the via hole or the contact hole are broadened, and a bottom width is not changed, therefore, a via hole or a contact hole with a wide top and a narrow bottom is formed.

FIGS. 1A through 1C are schematic, cross-sectional views showing a conventional method of fabricating a contact hole with a wide top and a narrow bottom.

Referring to FIG. 1A, a semiconductor substrate 100 is provided. A transistor including a gate conductive layer 103, a gate oxide layer 105, spacers 107, and a source/drain region 109 is formed on the substrate 100. An oxide layer 102 is formed over the substrate 100 by chemical vapor deposition (CVD). A patterned photoresist layer 104 is formed by photolithography. The photoresist layer 104 has an opening 106, which is the pattern for forming a subsequent contact hole. During the step of patterning the photoresist layer 104, some photoresist layer residue and by-products remain in the opening 106. Therefore, a descumming step is performed with oxygen plasma to clean away the photoresist layer residue and the by-products remaining in the opening 106 and to make a subsequent wet etching process progress efficiently. After the descumming step, the oxide layer 102 is fully exposed by the opening 106.

Turning to FIG. 1B, a wet etching process is performed on the oxide layer 102 exposed by the opening 106 to remove a portion of the oxide layer 102 so that a hole 108 is formed. Since the wet etching process is an anisotropic etching process, a portion of the oxide layer 102 below the photoresist layer 104 is also removed to form the hole 108 extending up to the bottom of the photoresist layer 104. The hole 108 is wider than the opening 106 (FIG. 1A). The size of the hole 108 is controlled by the wet etching time.

A baking step is performed with a hot plate at about 110° C. to remove a solvent in the photoresist layer 204, so the photoresist layer 204 is cured.

Turning to FIG. 1C, using the photoresist layer 104 (FIG. 1B) as a mask, the oxide layer 102 is anisotropically etched until the source/drain region 109 is exposed to form a contact hole 110 in the oxide layer 104. The photoresist layer 104 (FIG. 1B) is removed. At this point, the contact hole 10 is complete.

In the conventional method, the hole 108 (FIG. 1B), which is wider than the opening 106, is first formed in the oxide layer 102, and then the contact hole 110 with a wide top and a narrow bottom can be formed, as shown in FIG. 1C. Therefore, while filling with a metal layer in a later process, a step coverage ability can be improved.

However, many problems arise when the integration in integrated circuits is increased and the above-mentioned method is used. Since the hole is formed by the wet etching process, the profile of the subsequently formed contact hole is difficult to control. If the profile of the contact hole is not well controlled, a contact hole with a wider and deeper top may be formed so as to create an insufficient distance between two subsequently formed metal layers, consequently leading to a short phenomenon. In addition, if the via hole or the contact hole is too broad, it cannot satisfy a semiconductor design rule. The problems are especially serious when a via or contact hole dimension is 0.35 μm or smaller.

### SUMMARY OF THE INVENTION

Accordingly, the present invention provides an improved method for fabricating a contact hole. The method can form a contact hole with a wider top and a narrower bottom by a full etching process. Therefore, a profile of the contact hole is easily controlled.

To achieve these and other advantages and in accordance with the purpose of the invention, as embodied and broadly described herein, the invention provides a method for fabricating a contact hole. A semiconductor substrate is provided wherein a transistor is formed on the substrate. A dielectric layer is formed over the substrate. A patterned mask layer with an opening is formed on the dielectric layer. An UV curing treatment is performed on the mask layer. The dielectric layer is anisotropically etched using the mask layer as a mask to form a contact hole in the dielectric layer. The invention can be used in via hole fabrication.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1C are schematic, cross-sectional views showing a conventional method of fabricating a contact hole;

FIGS. 2A through 2C are schematic, cross-sectional views showing a method of fabricating a contact hole according to one preferred embodiment of this invention;

FIG. 3 is a cross-sectional view showing a method of fabricating a via hole according to one preferred embodiment of this invention; and

FIG. 4 is a cross-sectional view showing a method of fabricating a gate contact hole according to one preferred embodiment of this invention.

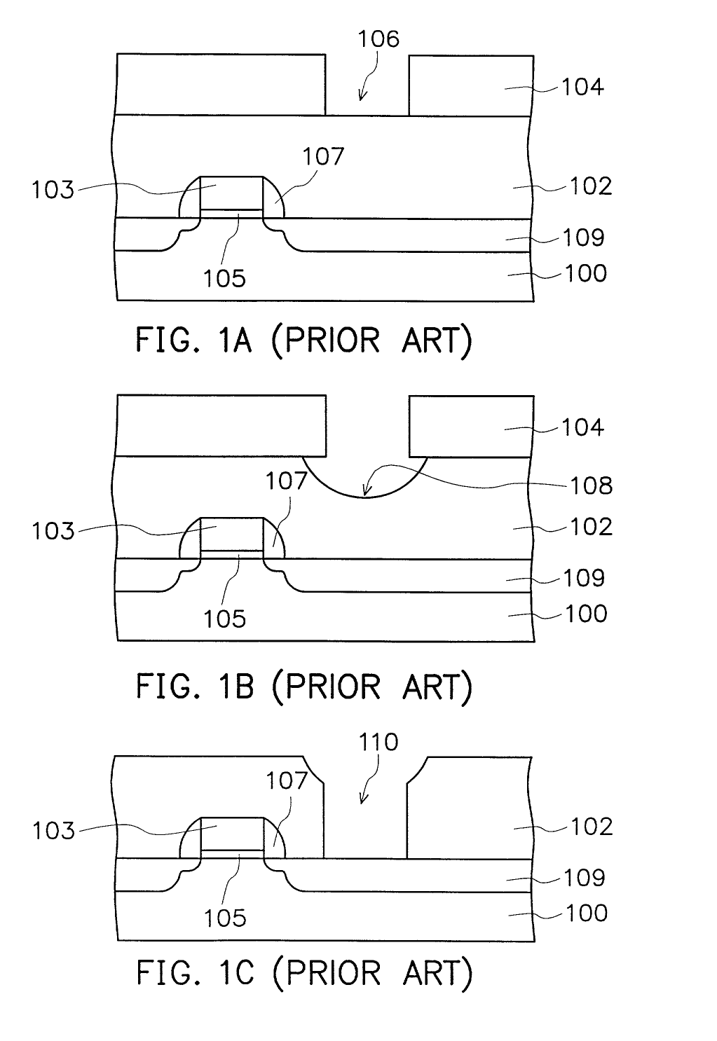

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

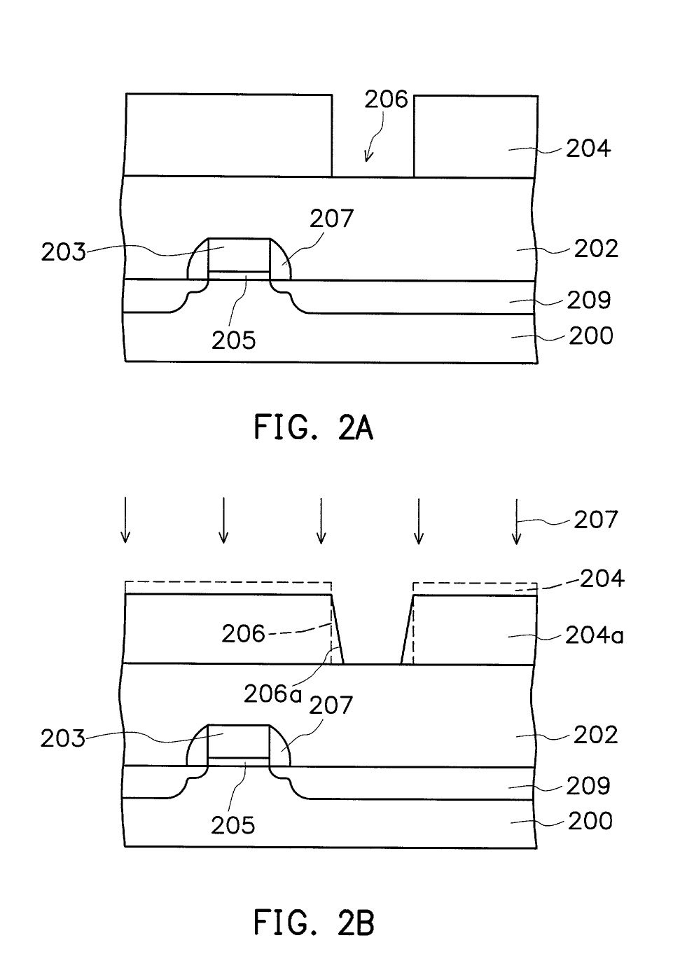

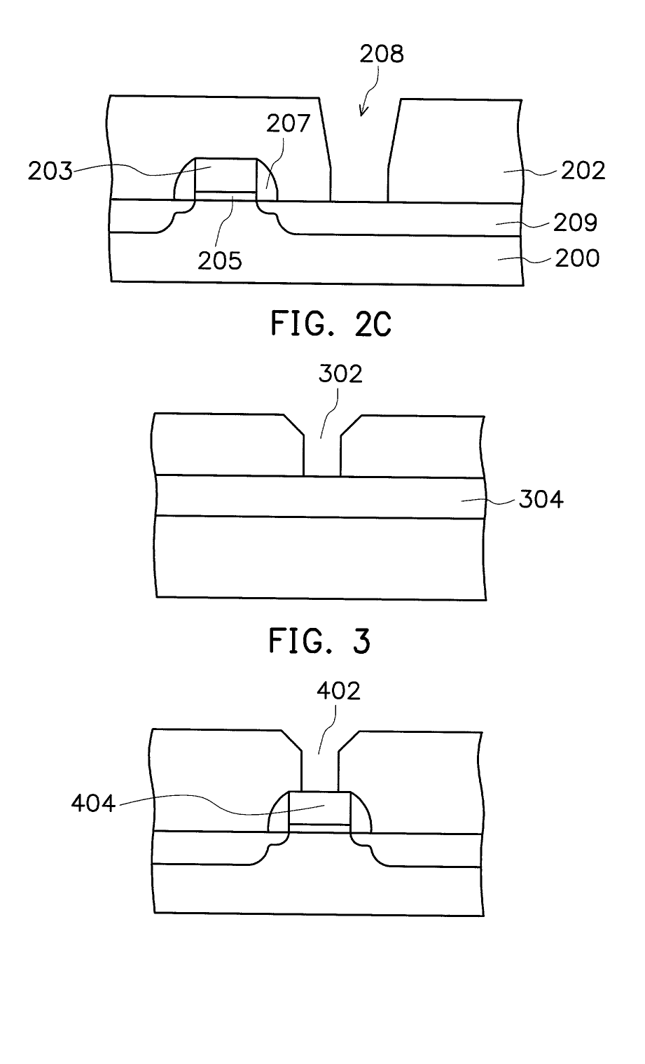

FIGS. 2A through 2C are schematic, cross-sectional views showing a method of fabricating a contact hole having a top corner with a tapered profile according to one preferred embodiment of this invention.

Referring to FIG. 2A, a semiconductor substrate 200 is provided. A transistor including a conductive layer 203, a gate oxide layer 205, spacers 207, and a source/drain region 209 is formed on the substrate 200. A dielectric layer 202 is formed over the substrate 200. The dielectric layer 202 includes, for example, silicon oxide (SiO₂), borophosphosilicate glass (BPSG), phosphosilicate glass (PSG), or another dielectric material with a low dielectric constant (k). The dielectric layer 202 is formed by, for example, chemical vapor deposition (CVD). A patterned mask layer 204 such as a photoresist layer is formed on the dielectric layer 202. The mask layer 204 has an opening 206 which is the pattern for forming a subsequent contact hole.

Turning to FIG. 2B, a pre-bake step, that is, an UV (ultra-violet) curing treatment (arrows 207) is performed on the mask layer 204. The mask layer 204 is exposed under the UV light so that the opening 206 is transformed as another opening 206a with a wider top and a narrower bottom. After the UV curing treatment (arrows 207), a baking step is performed. The baking step includes baking the mask layer 204 with a hot plate at about 100-130° C., for example. A solvent in the mask layer 204 is thus removed.

In the contrast with the conventional baking method, the invention exposes the mask layer 204 under the UV light to make the mask layer 204 cross-link and to reflow the mask layer 204. Thus sidewalls of the opening 206a are transformed to have a tapered profile with an inclination of about 60°-70°, therefore, the opening 206 having a wider top and a narrower bottom is formed, as shown in FIG. 2B. In FIG. 2B, some changes in photoresist layer 204 profiles are generated before the UV curing treatment (dashed line) and after the UV curing treatment (solid line). The surface level of the photoresist layer 204a is less than that of the photoresist layer 204. This is because a portion of the photoresist layer 204 reflows into the opening 206 so that the surface level of the photoresist layer 204a is decreased, the sidewalls of the photoresist layer 204 are transformed to have a tapered profile, and the opening 206a with a wider top and a narrower bottom is formed.

Turning to FIG. 2C, using the mask layer 204a (FIG. 2B) as a mask, the dielectric layer 202 is anisotropically etched until the source/drain region 209 is exposed to form a contact hole 208 in the dielectric layer 202. Since the opening 206a (FIG. 2B) has the wider top and the narrower bottom, while anisotropically etching the dielectric layer 202 to form the contact hole 208, the contact hole 208 profile is copied from the opening 206a profile. Therefore, the contact hole 208 with a wider top and a narrower bottom is formed.

Although the embodiment takes a contact hole as an example, the invention is also used in a via which is fabricated between two metal layers, or a contact hole exposing a gate conductive layer. FIG. 3 is a cross-sectional view showing a method of fabricating a via hole with a top corner having a tapered profile according to one preferred embodiment of this invention. FIG. 4 is a cross-sectional view showing a method of fabricating a gate contact hole with a top corner having a tapered profile according to one preferred embodiment of this invention. Since processes for forming the contact hole in FIG. 3 and the via hole in FIG. 4 are the same as the embodiment, detailed description is omitted here. In FIG. 3, a metal layer 304 is exposed by a via hole 302; in FIG. 4, a gate conductive layer 404 is exposed by a contact hole 404.

Table 1 shows profiles of a photoresist layer and a contact hole, respectively, with a hot plate curing and with an UV pre-bake curing while forming the contact hole in a semiconductor process for 0.5 μm line width.

TABLE 1

| | Conventional method | The invention |
|---|---|---|
| Pre-bake | 110° C. hot plate | 110-130° C. UV curing |
| PR profile (degree) | 79° | 65° |
| Hole width (top) | 0.6 μm | 0.88 μm |
| Hole width (bottom) | 0.48 μm | 0.48 μm |

Table 1 shows that the contact hole of the invention has a wider top and more highly tapered sidewalls than the conventional method so that while filling the contact hole with a conductive layer in later processes, the contact hole has a better step coverage ability.

In the conventional method, a wet etching process is performed to increase a width of the contact hole. In the invention, the wet etching process is not performed in the invention and a full dry etching process is performed; therefore, the invention can easily control the profile of the contact hole while forming the contact hole.

Since a wet etching process is not performed for removing residual materials on the photoresist layer in the invention, after the photoresist layer is patterned, oxygen plasma is not performed to remove the residual materials on the photoresist layer. Therefore, the processes are simplified.

The UV curing treatment in the invention is combined with a conventionally used baking process. The UV curing treatment is a pre-bake process, therefore, the invention is not more complex than the conventional method.

Additionally, the invention uses full dry processes; therefore, a profile of a contact hole is easily controlled.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a contact hole, comprising:
providing a semiconductor substrate comprising a transistor;
forming a dielectric layer over the substrate;
forming a patterned mask layer with an opening on the dielectric layer;
performing a UV curing treatment on the mask layer; and
anisotropically etching the dielectric layer using the mask layer as a mask to form a contact hole in the dielectric layer to expose a part of the transistor.

2. The method according to claim 1, wherein the UV curing treatment comprises baking the mask layer with a hot plate at about 100-130° C., and exposing the mask layer under an UV light.

3. The method according to claim 1, wherein the dielectric layer comprises oxide.

4. The method according to claim 1, wherein the dielectric layer is formed by chemical vapor deposition.

5. The method according to claim 1, wherein the mask layer comprises a photoresist layer.

6. The method according to claim 1, wherein the part of the transistor comprises a gate.

7. The method according to claim 1, wherein the part of the transistor comprises a source/drain region.

8. A method of fabricating a via hole, comprising:
forming a metal layer over a semiconductor substrate;
forming a dielectric layer over the substrate;
forming a patterned mask layer with an opening on the dielectric layer;
performing an UV curing treatment on the mask layer; and
anisotropically etching the dielectric layer using the mask layer as a mask to form a via hole in the dielectric layer to expose the metal layer.

9. The method according to claim 8, wherein the UV curing treatment comprises baking the mask layer with a hot plate at about 100-130° C. and exposing the mask layer under an UV light.

10. The method according to claim 8, wherein the dielectric layer comprises oxide.

11. The method according to claim 8, wherein the dielectric layer is formed by chemical vapor deposition.

12. The method according to claim 8, wherein the mask layer comprises a photoresist layer.
